(19) United States
(12) Patent Application Publication
(10) Pub. No.: US 2007/0252263 A1
(43) Pub. Date: Nov. 1, 2007

(54) Memory package structure

(75) Inventor: En-Min Jow, Hsinchu-City (TW)

Correspondence Address: BACON & THOMAS, PLLC, 625 SLATERS LANE, FOURTH FLOOR, ALEXANDRIA, VA, 22314, US

(73) Assignee: En-Min JOW, Hsinchu City (TW)

(21) Appl. No.: 11/806,286

(22) Filed: May 31, 2007

(30) Foreign Application Priority Data
Apr. 27, 2006 (TW) 96115069

(51) Int. Cl. H01L 23/48

(52) U.S. Cl. 257/690

(57) ABSTRACT

A memory package structure includes: a substrate having a first surface and a second surface, a first memory chip arranged on a chip-bearing area of the first surface and electrically connected with the substrate, an opening formed within a chip-bearing area of the substrate, a control chip arranged on the first memory chip within the opening and electrically connected with the substrate, at least a passive component arranged on the substrate, and a molding component covering the substrate, the first memory chip, the control chip and the passive component but exposing a portion of the second surface.

### BACKGROUND OF THE INVENTION

1. Field of the Invention

The present invention relates to a package structure of a semiconductor, and, more especially, to a memory package structure.

2. Description of the Prior Art

Along with the increasing of the memory capacity demand, the amount of the memory chip in one package is becoming more and more. Please refer to FIG. 1, it is illustrating the schematic diagram of a conventional memory package structure. Shown in FIG. 1, the memory chips 120 and 122 are stacked on the substrate 110 and arranged side by side with a control chip 130. In addition, at least a passive component 140 is arranged on the substrate 10, wherein, the memory chips 120, 122, and the control chip 130 are electrically connected with the substrate 110 respectively. A memory package structure is formed by molding the memory chips 120, 122, the control chip 130, and the passive component 140 with a molding component 150. A plurality of solder balls 160 is arranged under the substrate 110 as the connection points for connecting an external apparatus. However, expect for the memory capacity demand, how to reduce the scale of the memory package structure is an un-overcome issue.

### SUMMARY OF THE INVENTION

In order to overcome the foregoing problems, one object of the present invention is to provide a memory package structure. The control chip of the memory package structure is arranged under the memory chip and positioned within an opening of the substrate so as to reduce the scale of the memory package structure.

Another object of the present invention is to provide a memory package structure. The control chip of the memory package structure is arranged under the memory chip and positioned within an opening of the substrate so as to increase the space to place more memory chips and utilizes a molding component to form a memory card by a one-piece-form memory formation.

To achieve the foregoing purposes, one embodiment of the memory package structure includes: a substrate having a first surface and a second surface; a first memory chip arranged on a chip-bearing area of the first surface and electrically connected with the substrate; an opening formed within the chip-bearing area; a control chip arranged under the first memory chip within the opening and electrically connecting with the substrate; at least a passive component arranged on the substrate; and a molding component covering the substrate, the first memory chip, the control chip and the passive component but exposing a portion of the second surface.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram of a conventional memory package structure; and

FIG. 2, FIG. 3, FIG. 4, FIG. 5, and FIG. 6 are cross-sectional view diagrams of the memory package structure in accordance with different embodiment of the present invention.

### DETAILED DESCRIPTION OF THE INVENTION

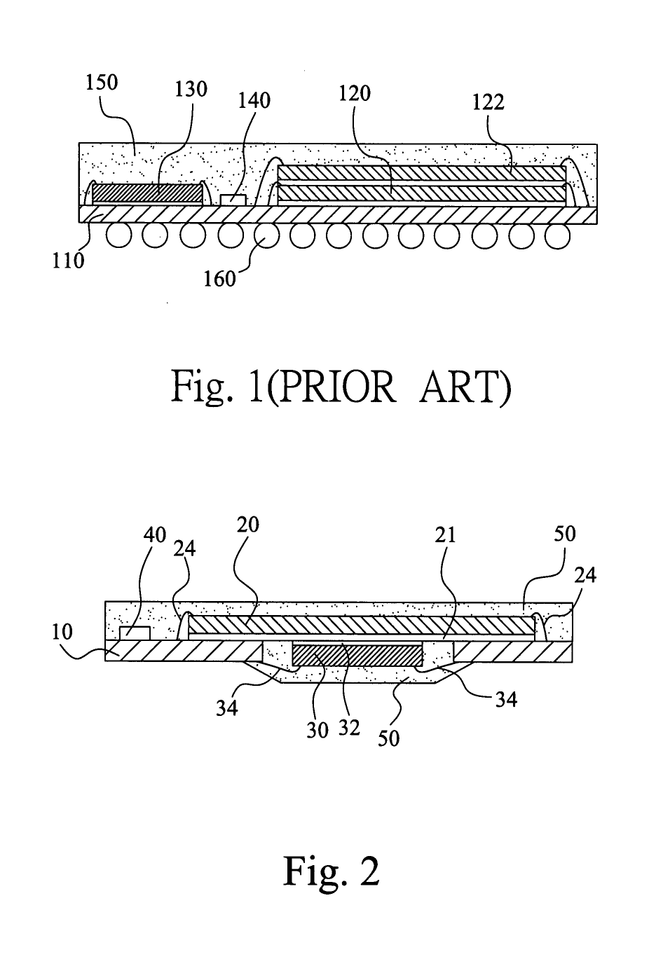

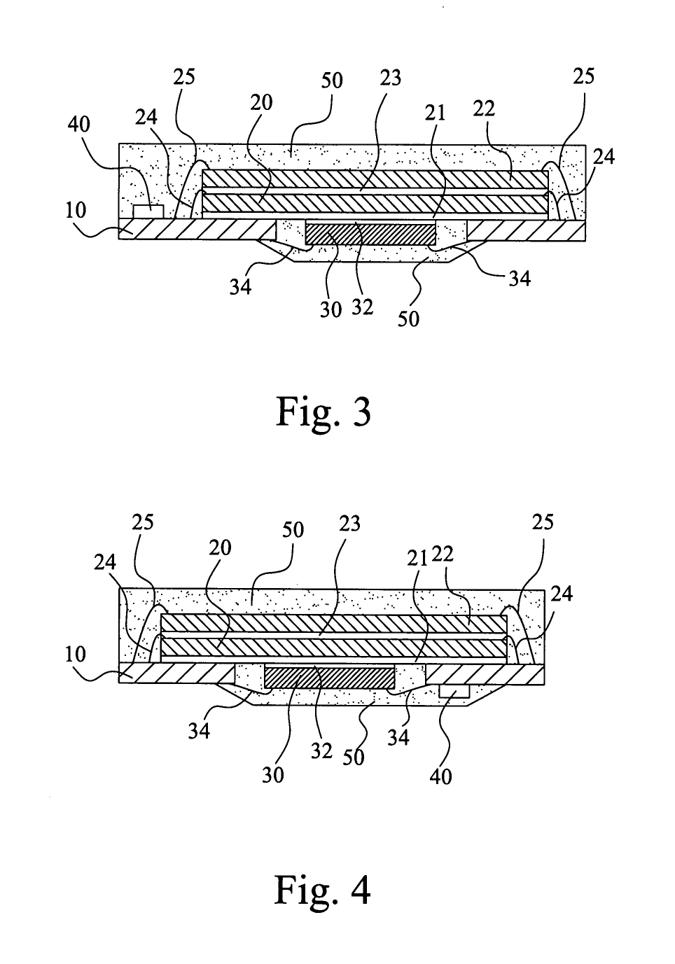

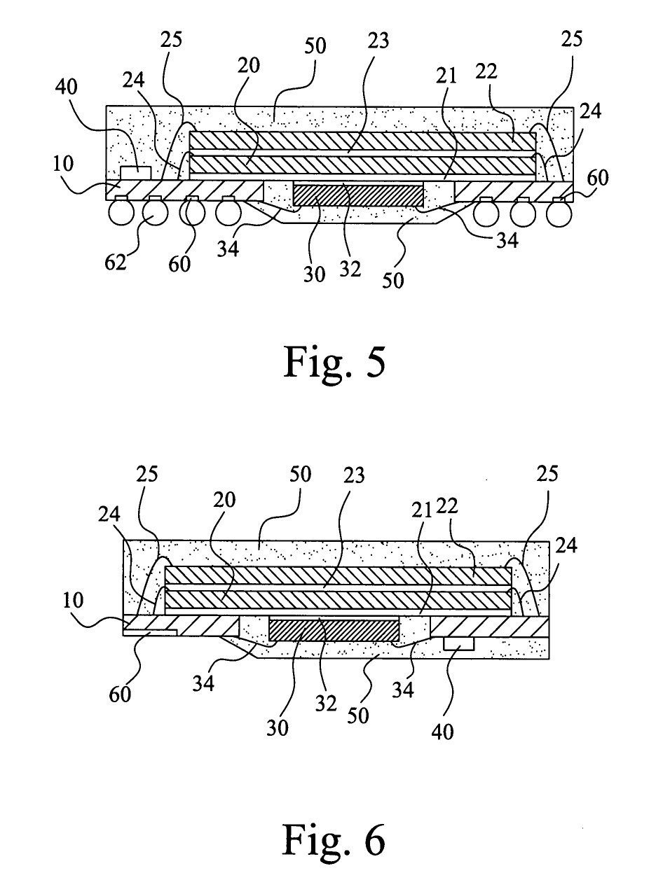

Referring to FIG. 2, FIG. 3, FIG. 4, FIG. 5, and FIG. 6, they are illustrating the cross-sectional view diagrams of the memory package structure in accordance with different embodiment of the present invention. Shown in FIG. 2, the memory package structure in the present embodiment includes a substrate 10 having a first surface and a second surface, wherein the substrate 10 is a printed circuit board (PCB) with circuit thereon. The substrate 10 is made of polyimide, glass, alumina, epoxy, beryllium-oxide, elastic or the combination thereof. A first memory chip 20 is set on a chip-bearing area of the first surface of the substrate 10 by an adhesive layer 21, and the first memory chip 20 is electrically connected to the substrate 10 via an electrical connection structure. In this embodiment, the electrical connection structure is utilizing a plurality of wires 24 to electrically connect the first memory chip 20 and the first surface of the substrate 10.

To continue the above explanation, within the chip-bearing area, at least an opening (not labeled) of the substrate 10, and, within the opening, a control chip 30 is arranged on the first memory chip 20 and positioned within the opening and the control chip 30 is set on the first memory chip 20 by an adhesive layer 32. And, the control chip 30 is electrically connected to the second surface of the substrate 10 by a bonding structure, such as a plurality of wires 34.

Besides, in the present invention, at least a passive component 40 is arranged on the first surface of the substrate 10 and a molding component 50 is used to cover the substrate 10, the first memory chip 20, the control chip 30, the passive component 40, and the wires 24, 34, but to expose a portion of the second surface of the substrate 10.

Accordingly, the first memory chip 20, in one embodiment, can electrically connect the substrate 10 with a plurality of solder balls (not shown), and in another embodiment, the control chip 30 can be set on the first memory chip 20 via the adhesive layer 21.

In an embodiment, please refer to FIG. 3, a second memory chip 22, in the present embodiment, is stacked on the first memory chip 20 with an adhesive layer 23, and the second memory chip 22 is electrically connected to the substrate 10 by a bonding structure, such as a plurality of wires 24.

According to an embodiment shown in FIG. 4, the passive component 40 is arranged on the second surface of the substrate 10 instead of the first surface.

Accordingly, please refer to FIG. 5, the memory package structure further includes a plurality of conductive contacts 60, such as solder pads, arranged on the exposed second surface of the substrate 10. And, a plurality of solder balls 62 are arranged on the solder pads in order to connect to an external component or apparatus.

In an embodiment, referring to FIG. 6, a plurality of conductive contacts 60 is arranged on the exposed second surface of the substrate 10 as a plurality of golden fingers to be the external connection of the memory card. The control chip 30 is within the opening of the substrate 10 under the first memory chip, and the passive component 40 is arranged on the second surface where is near the opening. Thus, the first surface of the substrate 10 is vacuumed out to have a larger space for more memory chips so as to increase the memory capacity of the memory card. Thus, the molding component 50 can be formed as the appearance of the memory card by a one-piece-form formation.

To sum up the foregoing descriptions, the present invention is to provide the memory package structure. The memory package structure is to place the control chip under the memory chip and within the opening of the substrate so as to reduce the scale of the memory package structure. Besides, to place the passive component on the second surface which is near the opening can drop the scale of the memory package structure either. And, the memory package structure of the present invention can applied in the package process of the memory card, the space of the first surface for placing the memory chip can be increased by place the control chip under the memory chip and within the opening of the substrate. And the molding component of the memory package structure can be formed as an appearance of the memory card by a one-piece-form formation. The design of the memory package structure can increase the space of the memory card to place more memory chips so as to increase the memory capacity.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A memory package structure, comprising:
a substrate having a first surface and a second surface;
a first memory chip arranged on a chip-bearing area of said first surface and electrically connected with said substrate;
an opening formed within said chip-bearing area of said substrate;
a control chip arranged under said first memory chip within said opening and electrically connected with said substrate;
a passive component arranged on said substrate; and
a molding component covering said substrate, said first memory chip, said control chip and said passive component but exposing a portion of said second surface.

2. The memory package structure according to claim 1, wherein said substrate is a printed circuit board.

3. The memory package structure according to claim 1, wherein said substrate is made of polyimide, glass, alumina, epoxy, beryllium-oxide, elastic and the combination thereof.

4. The memory package structure according to claim 1, further comprising an adhesive layer between said first memory chip and said substrate.

5. The memory package structure according to claim 1, further comprising an electrical connection structure to electrically connect said first memory chip and said substrate on said first surface.

6. The memory package structure according to claim 5, wherein said electrical connection structure includes a plurality of wires or solder balls.

7. The memory package structure according to claim 1, further comprising a bonding structure to electrically connect said control chip and said substrate on said second surface.

8. The memory package structure according to claim 1, further comprising an adhesive layer between said control chip and said first memory chip.

9. The memory package structure according to claim 1, wherein said passive component is arranged on said first surface.

10. The memory package structure according to claim 1, wherein said passive component is arranged on said second surface.

11. The memory package structure according to claim 1, further comprising a second memory chip stacked on said first memory chip.

12. The memory package structure according to claim 11, further comprising an adhesive layer between said first memory chip and said second memory chip.

13. The memory package structure according to claim 11, further comprising a bonding structure to electrically connect said second memory chip and said substrate.

14. The memory package structure according to claim 1, further comprising a plurality of conductive contacts on said exposed second surface.

15. The memory package structure according to claim 14, wherein said conductive contact includes a plurality of golden fingers.

16. The memory package structure according to claim 14, wherein said conductive contact includes a plurality of solder pads.

17. The memory package structure according to claim 16, further comprising a plurality of solder balls on said solder pads respectively.
